(19) United States
(12) Patent Application Publication
(10) Pub. No.: US 2005/0103978 A1
(43) Pub. Date: May 19, 2005

(54) Remote controlling device with visual recognition functions

(76) Inventors: Lian Yang, Xiaolan Town (CN); Bijun He, Xiaolan Town (CN); Xiaogui Yao, Xiaolan Town (CN); Shu Li, Xiaolan Town (CN)

Correspondence Address: KAPLAN & GILMAN , L.L.P., 900 ROUTE 9 NORTH, WOODBRIDGE, NJ, 07095, US

(21) Appl. No.: 10/845,866

(22) Filed: May 14, 2004

(30) Foreign Application Priority Data
Nov. 17, 2003 (CN) 200310112143.3

(51) Int. Cl. H01L 27/00

(52) U.S. Cl. 250/208.1; 250/214 AG

(57) ABSTRACT

A controlling device with visual recognition functions comprises a switch, a CCD camera and an infrared-emitting diode; it is installed with a power source, a visual recognition circuit, a signal processing circuit and a remote controlling circuit composed of signal emitting circuit; the power source supplies electric power to the visual recognition circuit, the signal processing circuit and the remote controlling circuit composed of signal emitting circuit; the visual recognition circuit is connected to the signal processing circuit and the signal processing circuit is connected to the signal emitting circuit. A complete remote controlling system is composed by the remote controlling device and a receiving part installed in the controlled device.

### BACKGROUND OF INVENTION

The present invention relates to an infrared remote controlling device in the remote controlling field, and particularly a remote controlling device with visual recognition functions.

Currently, there are neither technical documents, publications about similar technical solutions, nor any same product in the market or in practical use; the existing technologies similar to the present invention are “general infrared remote controller”, “wireless mouse remote controlling device” and “button remote controlling device with touch pad”.

The remote control system of the “General infrared remote controller” is composed of an infrared-emitting device with buttons and an infrared-receiving device.

The remote control system of the “wireless mouse remote controlling device” is composed of an infrared-emitting device with a wireless mouse and an infrared-receiving circuit and an OSD operating circuit on the controlled device.

The remote control system of the “button remote controlling device with touch pad” is composed of an infrared-emitting device with a touch pad button and an infrared-receiving device on the controlled device.

All the controlling devices of the above technologies do not have the visual recognition functions.

### SUMMARY OF THE INVENTION

It is the main object of the present invention to overcome the disadvantage of the existing remote controlling devices that no visual recognition function is incorporated, and to provide a newly structured remote controlling device with visual recognition functions. This remote controlling device makes the receipting devices perform remote operation according to the operator's will after detecting the control signals by recognizing the OSD information appearing on the terminal displays of the controlled devices and sending the OSD operating information by infrared means.

The following solutions were employed by the present invention to overcome the technical disadvantages:

The remote controlling device with visual recognition functions according to the present invention constitutes a complete remote controlling system together with the receiving part of the controlled device. The receiving device is installed in the main body of the controlled machine, and the controlling device is an independent electronic device with a controlling switch, a CCD camera and an infrared-emitting diode; it is installed with a power source, a visual recognition circuit, a signal processing circuit and a remote controlling circuit composed of signal emitting circuit; the power sources supplies electric power to the visual recognition circuit, the signal processing circuit and the remote controlling circuit composed of signal emitting circuit; the visual recognition circuit is connected to the signal processing circuit and the signal emitting circuit.

The technical problems can also be further solved by employing the following solutions according to the present invention:

The aforementioned remote controlling device with visual recognition functions, wherein the number of the controlling switch is at least one.

The aforementioned remote controlling device with visual recognition functions, wherein the visual recognition function circuit is composed of a photoreceptive CCD circuit connecting to an image automatic gain control circuit (AGC), or of an integrated circuit with photoreceptive CCD circuit and image automatic gain control circuit (AGC) built in it; wherein the signal processing circuit is constructed by connecting an analogue-to-digital converter (A/D converter) to a memory chip (ROM) and a main computation unit chip (MCU), or by connecting a chip with two of the following three functions, A/D converter, ROM and MCU, to a chip with the rest one function, or is composed of an IC chip with all the three functions; the signal emitting circuit is constructed by a chip with MCU functions driving an infrared-emitting diode.

The aforementioned main computation unit chip (MCU) has an OSD operating system installed in it.

The aforementioned A/D converter has a converting precision higher than 8 bit resolution.

The aforementioned controlling switch is connected to an input which is connected to the pin of the main computation unit chip (MCU).

The aforementioned ROM has a capacity bigger than 1 Mb, and is suitable to process signals with a resolution higher than 256×256.

Holding the remote controlling device, aiming roughly at the target and starting operation, the content to operate on and a mouse-like cursor will appear on the display; when the remote controlling device aims at an OSD target, the cursor will also move on it. After moving the remote controlling device until it aims at an OSD target to be adjusted or enters a selected OSD target adjusting status, the operation can be performed by pressing the buttons (controlling switches).

The remote controlling device works as follows: as the photoreceptive CCD camera receives the OSD signal from the display (in the form of CRT, LCD, PDP, LED, OED, etc.) of the controlled device, the signal will be processed by the image automatic gain control circuit (AGC), converted to digital signal by an A/D converter with a resolution higher than 8 bit, inputted to a ROM with image storage function, and then calculated by the driving software burned into the MCU. The MCU will then drive the infrared-emitting device to send remote controlling instructions.

The target acquired straight in front of the photoreceptor will be projected on the sensor plate of the CMOS image sensor through an object lens of the remote controlling device. When the remote controlling device moves with respect to the image on the display in any direction, the projected image on the sensor will move towards an opposite direction. If we view the display as an mathematical coordinate system, when the remote controlling device moves, the MCU will process the offset angle of the projection angle α in the horizontal direction X-Δαₓ, and the offset angle of the projection angle β in the vertical direction Y-Δβ_{y}; the ratio of the minimum discriminate angle against the maximum valid operating angle (α0, β0) will be sent out as controlling signals. Δαₓ in the horizontal direction X occupies n digits of the infrared carrier wave emitting code, and Δβ_{y} in the vertical direction Y occupies m digits of the infrared carrier wave emitting code, thus it makes the maximum resolution of the controlled parameter targets n×m, and generates (n×m)×(n×m) controlled parameters by the second layer of the software configuration.

Generally, the receiving part of the controlled device compromises an infrared receptor IRR, a CPU and an OSD circuit. The IRR receives the remote controlling instructions or operating data and inputs them into the CPU for processing, thus forming the corresponding parameters and OSD contents, which will then go through the OSD circuit and be outputted as responding operating signals; these signals will be overlapped and inputted into the video driving circuit; the display of the controlled device will then display next OSD operating interface or just close the current OSD operating interface; at the same time, operations on the OSD interface, such as tuning, band selection, graph quality adjustment, audio processing adjustment, etc., will be executed.

The visual recognition function circuit, the signal processing circuit and the signal emitting circuit mentioned in this disclosure are existing technologies.

Compared to the state of the art, the present invention enjoys significant advantages and beneficial effects. As can be seen from above technical solutions, the present invention obtains the objective of multi-level, multi-layer, simple and prompt operation by using the remote controller CCD device to collect signals, controlling the OSD operating system to perform background operation and using remote controlling infrared emitting and receiving system to operate the foreground controlled devices. The present invention uses an image movement method, by recognizing and processing the movement in the image forming X-Y coordinate, to judge the moving direction and the offset angles Δαₓ, Δβ_{y}, and controls the adjustment parameters by aiming at an adjustment value or a control value on the target; this kind of operation is far more convenient than other remote control methods, and has inventive step in it. Because the remote controlling device actually takes α0 and β0 as basic references, the implementation is simple and reliable. Currently, all the displays with a displaying area bigger than 15 to 100 inches and videos or graphic signal transporting devices correspondingly, such as amplifiers, VCDs, set-top boxes, video network players, DVD and other video players, CATV receptors, satellite TV receptors, etc., have interfaces showing detailed operating contents (OSD); the operators will find it easy and comfortable to perform remote control over them using the present invention.

In conclusion, the present invention is a remote control device with visual recognition functions. It provides significant improvement both in the structure and the functions, and has an easy-to-use and practical-to-use effect. It also improves the functions, thus making it more suitable for practical use. It involves an inventive step and technical improvements and has industrial practicality.

Specific implementations of the present invention will be illustrated with reference to the following embodiments and figures.

### DESCRIPTION OF THE DRAWINGS

FIG. 1 is an electronic circuit diagram of a one-button operating method according to the present invention;

FIG. 2 is an electronic circuit diagram of a two-button operating method according to the present invention;

FIG. 3 is an electronic circuit diagram of a three-button operating method according to the present invention;

FIG. 4 is a diagram of the electronic circuit between the receiving part of a television as a controlled device of the present invention and the original device;

FIG. 5 is a diagram of the electronic circuit between the receiving part of an amplifier in a home theatre as a controlled device of the present invention and the original device;

FIG. 6 is a diagram of the electronic circuit between the receiving part of a DVD player as a controlled device of the present invention and the original device.

Following are the meanings of the abbreviation in those figures:
CCD—a charge coupled device
AGC—an image automatic gain control circuit
A/D—an analogue-to-digital converter
MCU—a driving chip with CPU functions
ROM—a memory chip
IR—an infrared emitter
K—a one-button switch
K1—the first of a two-button switch
K2—the second of a two-button switch
KA—the first of a three-button switch
KB—the second of a three-button switch
KC—the third of a three-button switch
Receiver—a high frequency receiver
Demodulator—a medium frequency and video demodulator circuit
Audio—an audio circuit
Video—a video circuit
IRR—an infrared signal receiver
Tvset CPU—a CPU which is installed in a TV set to process remote control signals
Amplifier CPU—a CPU which is installed in the amplifier to process remote control signals
DVD CPU—a CPU which is installed in the DVD player to process remote control signals.

### DETAILED DESCRIPTION

With reference to the drawings and preferred embodiment, the specific implementation, the structure, the properties and the functions of a remote controlling device with visual recognition functions according to the present invention are illustrated in detail as follows.

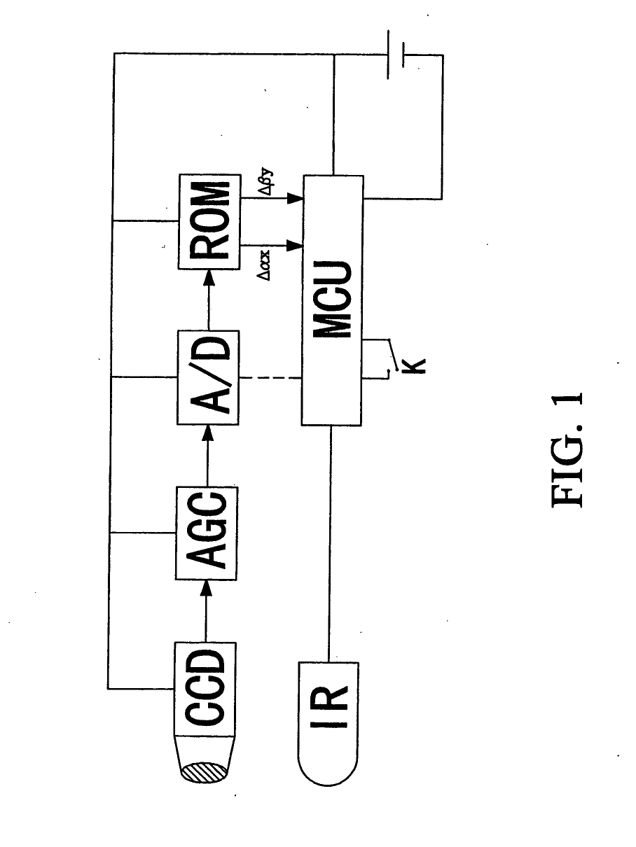

The present invention is a remote controlling device with visual recognition functions. It compromises a shell, an electronic circuit board, a CCD camera, an infrared-emitting diode, and control buttons. Referring to FIG. 1, 2 and 3, the electronic circuit board is composed of a power source, a visual recognition function circuit, a signal processing circuit and a signal emitting circuit. The visual recognition circuit is constructed by connecting a photoreceptive circuit to an image automatic gain control circuit; American Bell's 3.3V micro camera 900 WC, which integrates CCD and AGC circuits, was chosen. The signal processing circuit is constructed by an A/D converter converting the inputted analogue image signals into digital signals and outputting to the ROM. The MCU reads button control signals from the inputting interface and the horizontal and perpendicular excursion signals from ROM, and analyses them using the burned in software to generate control instructions or operating data; TMS320C6416-6E3, which includes A/D converting circuit, ROM and MCU, was chosen as the MCU. The infrared-emitting diode converts the output electric signals from MCU into infrared signals and outputs them to the receiving part of the controlled device; IR5143CA was chosen.

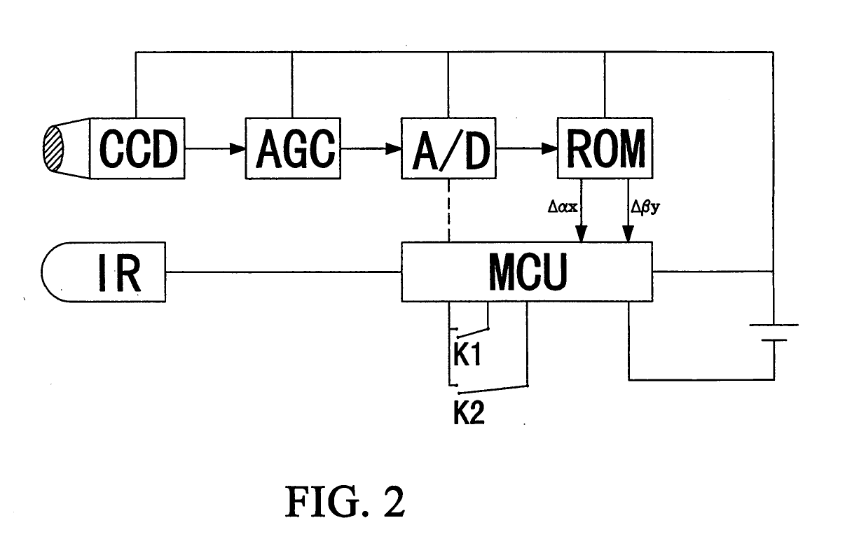

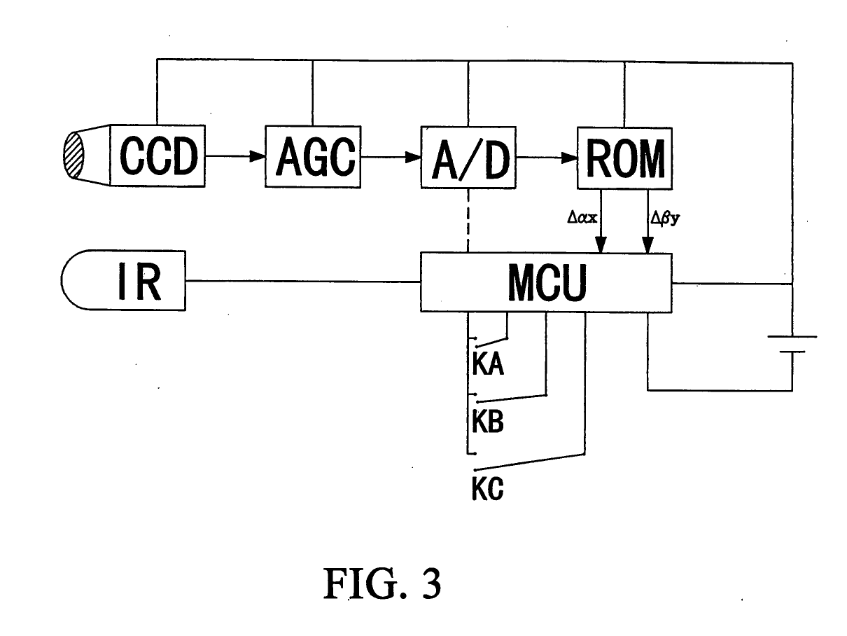

The controlling switch is a two-contract-point button, one of which connects to a public end and the other connects to an input end. Similarly, as shown in FIG. 2 and 3, in the case of two controlling switches, two input ends and one public end need to be connected, while in the case of three controlling switches, three input ends and one public end need to be connected. Generally, for N controlling switches, N input ends and one public end need to be connected.

All the circuits and components are connected using standard interfaces.

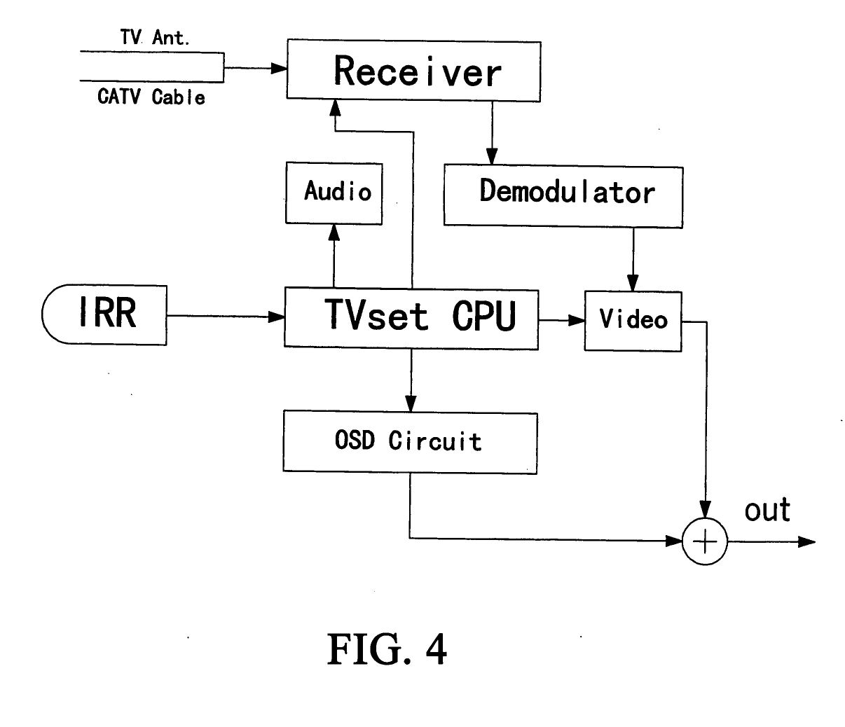

Refer to FIG. 4, 5 and 6, for different controlled devices, different receiving circuits need to be installed in order to couple with the remote controlling device according to the present invention. The basic part of the receiving circuit is constructed by connecting an IRR to intelligent signal CPU and OSD circuit. KIR304DR was chosen as the infrared receptor (IRR).

FIG. 4 is a diagram of the electronic circuit between the receiving part of a television as a controlled device of the present invention and the original device. The Tvset CPU installed in the TV receptor connects to the IRR and receives the infrared signals from IRR. The signals will then be outputted to the audio circuit, the video circuit, the TV high frequency receiver circuit and the OSD circuit after processing. The TV high frequency receiving circuit receiver connects to the TV Ant or CATV Cable. The signals it receives will be sent to the medium frequency and the demodulator circuits. The signals from the medium frequency and the demodulator circuits will then be outputted to the video circuit. The output signals to the display will then be generated by overlapping the outputs from the medium frequency and demodulator circuit and the OSD circuit.

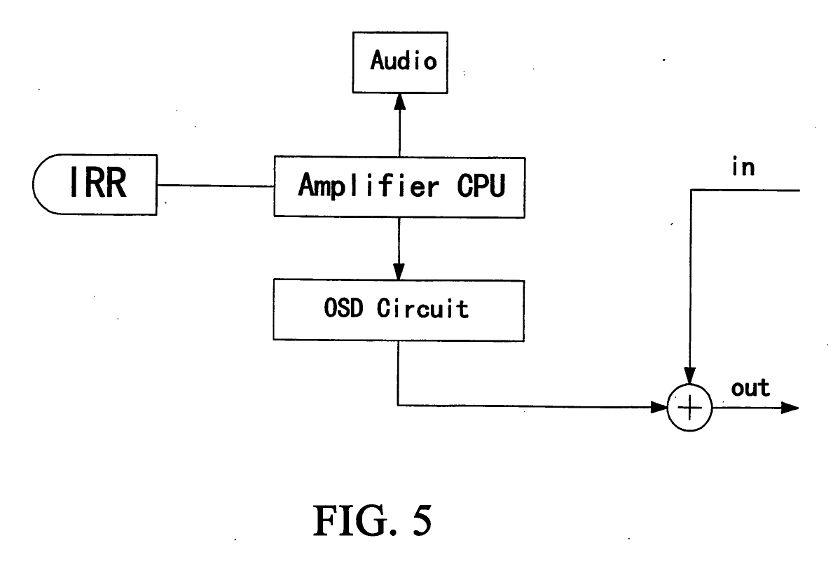

FIG. 5 is a diagram of the electronic circuit between the receiving part of an amplifier in a home theatre as a controlled device of the present invention and the original device. The Amplifier CPU installed in the home theatre amplifier connects to the IRR, receives its signals and outputs them to the audio circuit and the OSD circuit after processing. The output signals to the display will then be generated by overlapping the output signals from the OSD circuit and the input signals from the video circuit.

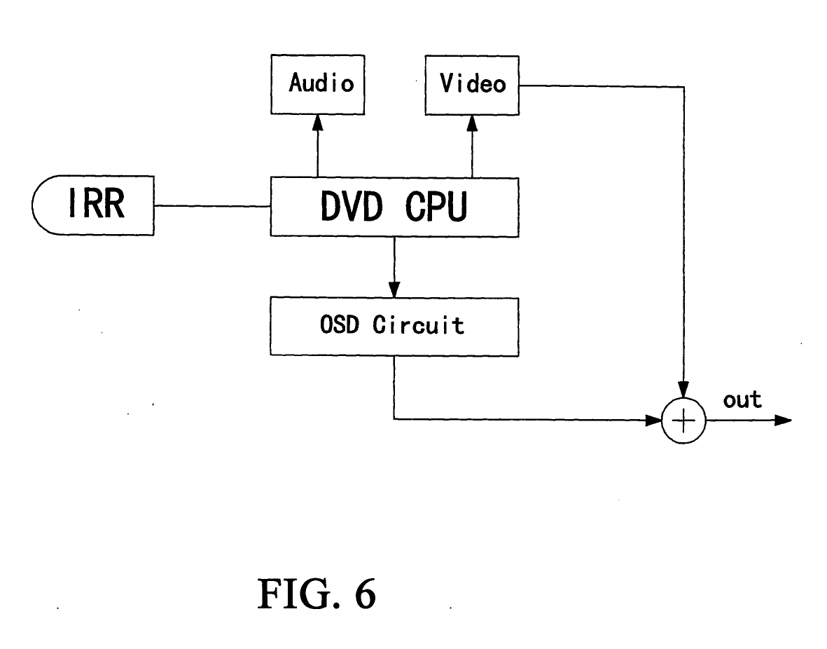

FIG. 6 is a diagram of the electronic circuit between the receiving part of a DVD player as a controlled device of the present invention and the original device. The DVD CPU in the DVD player connects to the IRR, receives its signals and sends them to the audio circuit, the video circuit and the OSD circuit. The output signals to the display will then be generated by overlapping the output signals from the OSD circuit and the video circuit.

Although preferred embodiments of the present invention have been described for illustrative purposes, those skilled in the art will understand that various modifications, additions and substitutions are possible, without departing from the scope and spirit of the invention as disclosed in the accompanying claims.

1. A remote controlling device with visual recognition functions comprising a shell, wherein the shell of the remote controlling device has a controlling switch, a CCD camera and an infrared emitting diode installed on it, and a remote controlling circuit composed of a power source, a visual recognition circuit, a signal processing circuit and a signal emitting circuit installed in it; the power source supplies electric power to the visual recognition circuit, the signal processing circuit and the signal emitting circuit; the visual recognition circuit connects to the signal processing circuit and the signal emitting circuit.

2. The remote controlling device with visual recognition functions as claimed in claim 1, wherein there is at least one of the aforementioned controlling switches.

3. The remote controlling device with visual recognition functions as claimed in claim 1, wherein the visual recognition circuit is constructed by connecting a photoreceptive CCD circuit to an image automatic gain control circuit (AGC), or is composed of an integrated circuit with a photoreceptive CCD circuit and an image automatic gain control circuit (AGC) embedded inside it; the signal processing circuit is constructed by connecting an analog-to-digital converter (A/D) chip to a ROM chip and a main computation unit chip (MCU), or connecting a chip with two of the following three functions, A/D converter, ROM and MCU, to a chip with the rest one function, or is composed of an IC chip with all the three functions; the signal emitting circuit is constructed by a chip with MCU functions driving an infrared-emitting diode.

4. The remote controlling device with visual recognition functions as claimed in claim 3, wherein the main computation unit chip (MCU) has an OSD operating system installed in it.

5. The remote controlling device with visual recognition functions as claimed in claim 3, wherein the A/D converter has a converting precision higher than 8 bit resolution.

6. The remote controlling device with visual recognition functions as claimed in claim 2, wherein the controlling switch is connected to an input which is connected to the pin of the main computation unit chip (MCU).

7. The remote controlling device with visual recognition functions as claimed in claim 3, wherein the ROM has a capacity bigger than 1 Mb, and is suitable to process signals with a resolution higher than 256×256.

8. The remote controlling device with visual recognition functions as claimed in claim 3, wherein the controlling switch is connected to an input which is connected to the pin of the main computation unit chip (MCU).
